(19) United States
(12) Patent Application Publication
(10) Pub. No.: US 2025/0316590 A1
(43) Pub. Date: Oct. 9, 2025

(54) SEMICONDUCTOR DEVICE INCLUDING ARRAY OF CONDUCTIVE LINES

(71) Applicant: SK hynix Inc., Gyeonggi-do (KR)

(72) Inventor: Heon Yong CHANG, Gyeonggi-do (KR)

(21) Appl. No.: 18/908,796

(22) Filed: Oct. 8, 2024

(30) Foreign Application Priority Data
Apr. 8, 2024 (KR) 10-2024-0047603

(51) Int. Cl. H01L 23/528; H10B 12/00

(52) U.S. Cl. CPC H01L 23/528; H01L 23/5283; H10B 12/482; H10B 12/488

(57) ABSTRACT

A semiconductor device includes an array of a first lower conductive line and a second lower conductive line, an array of a first upper conductive line and a second upper conductive line, and an array of a first contact and a second contact. The first upper conductive line includes a first end located over at least a portion of the first lower conductive line, and the second upper conductive line includes a second end located over at least a portion of the second lower conductive line. The second end is spaced apart from the first end in a diagonal direction with respect to a direction in which the first and second lower conductive lines extend.

### CROSS-REFERENCE TO RELATED APPLICATIONS

The present application claims priority under 35 U.S.C. 119(a) to Korean Patent Application No. 10-2024-0047603, filed on Apr. 8, 2024, which is incorporated herein by reference in its entirety.

### BACKGROUND

### 1. Technical Field

Embodiments of the present disclosure generally relate to an integrated circuit device and, more particularly, to a semiconductor device including an array of conductive lines.

### 2. Related Art

A semiconductor device may be formed by integrating integrated circuits (IC) on a semiconductor substrate or a semiconductor wafer. The semiconductor device includes a connection structure in which multi-layered conductive lines are connected to each other. The lower conductive lines and upper conductive lines of the connection structure are electrically connected to each other by conductive contacts. The upper conductive line located relatively lower and another conductive layer located relatively higher are electrically isolated from each other by an interlayer insulation layer. As a pattern width of each of the conductive lines constituting the semiconductor device gradually decreases, electrical isolation between the conductive lines becomes increasingly difficult and electrical isolation between the conductive lines located relatively lower and the conductive layers located relatively higher is also becoming increasingly more difficult.

### SUMMARY

An embodiment of the present disclosure may present a semiconductor device including a first lower conductive line and a second lower conductive line that are arranged over a semiconductor substrate, an insulation layer covering the first and second lower conductive lines, a first upper conductive line and a second upper conductive line that are arranged over the insulation layer, a first contact connecting the first upper conductive line to the first lower conductive line, and a second contact connecting the second upper conductive line to the second lower conductive line. The first upper conductive line may include a first end located over at least a portion of the first lower conductive line. The second upper conductive line may include a second end located over at least a portion of the second lower conductive line. The second end may be spaced apart from the first end in a first diagonal direction with respect to a first direction in which the first and second lower conductive lines extend.

An embodiment of the present disclosure may present a semiconductor device including a first lower conductive line and a second lower conductive line that are arranged over a semiconductor substrate, a middle conductive line intersecting the first and second lower conductive lines, an insulation layer covering the first and second lower conductive lines, a first upper conductive line and a second upper conductive line that are arranged over the insulation layer, a first contact that connects the first upper conductive line to the first lower conductive line, and a second contact connecting the second upper conductive line to the second lower conductive line. A first distance in which a first end of the first upper conductive line may be spaced apart from the middle conductive line is longer than a second distance in which a second end of the second upper conductive line is spaced apart from the middle conductive line.

An embodiment of the present disclosure may present a semiconductor device including a first lower conductive line and a second lower conductive line that are arranged over a semiconductor substrate, a middle conductive line intersecting the first and second lower conductive lines, an insulation layer covering the first and second lower conductive lines, a first upper conductive line and a second upper conductive line that are arranged over the insulation layer, a first contact connecting the first upper conductive line to the first lower conductive line, a second contact connecting the second upper conductive line to the second lower conductive line, a storage node connected to the semiconductor substrate, a capacitor dielectric layer covering the storage node, and a plate node covering the capacitor dielectric layer. The plate node may be spaced apart from a first end of the first upper conductive line and a second end of the second upper conductive line in a direction in which the first lower conductive line extends.

### BRIEF DESCRIPTION OF THE DRAWINGS

FIG. 1 is a schematic view illustrating a semiconductor device according to an embodiment of the present disclosure.

FIG. 2 is a schematic plan view illustrating a semiconductor device according to an embodiment of the present disclosure.

FIG. 3 is a schematic plan view illustrating arrays of conductive lines of the semiconductor device in FIG. 2.

FIG. 4 is a schematic cross-sectional view illustrating a cross-sectional shape along a line A-A′ in FIG. 3.

FIG. 5 is a schematic cross-sectional view illustrating a cross-sectional shape along a line B-B′ in FIG. 3.

FIG. 6 is a schematic plan view illustrating arrays of conductive lines of the semiconductor device according to an embodiment of the present disclosure.

FIG. 7 is a schematic plan view illustrating a semiconductor device according to an embodiment of the present disclosure.

FIG. 8 is a schematic cross-sectional view illustrating a cross-sectional shape along a line A-A′ in FIG. 7.

FIG. 9 is a schematic cross-sectional view illustrating a cross-sectional shape along a line B-B′ in FIG. 7.

FIG. 10 is a schematic cross-sectional view illustrating a semiconductor device according to an embodiment of the present disclosure.

FIG. 11 is a schematic plan view illustrating a semiconductor device according to an embodiment of the present disclosure.

FIG. 12 is a schematic cross-sectional view illustrating a cross-sectional shape along a line A-A′ in FIG. 11.

FIG. 13 is a schematic cross-sectional view illustrating a cross-sectional shape along a line B-B′ in FIG. 11.

FIG. 14 is a schematic plan view illustrating an effect by a semiconductor device according to an embodiment of the present disclosure.

FIG. 15 is a schematic plan view illustrating a semiconductor device according to an embodiment of the present disclosure.

FIG. 16 is a schematic cross-sectional view illustrating a cross-sectional shape along a line A-A′ in FIG. 15.

FIG. 17 is a schematic cross-sectional view illustrating a cross-sectional shape along a line B-B′ in FIG. 15.

### DETAILED DESCRIPTION

The terms used herein may correspond to words selected in consideration of their functions in the presented embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

In the description of the present disclosure, descriptions such as “first” and “second,” “upper,” “middle,” and “lower” are for distinguishing elements, and are not used to limit the elements themselves or to imply a specific order.

The embodiments of the present disclosure can be applied to the field of technology that implements integrated circuit devices such as DRAM, NAND FLASH, PCRAM, or ReRAM devices. In addition, the embodiments of the present disclosure can also be applied to the field of technology that implements memory devices storing data or logic devices performing logical operations. The embodiments of the present disclosure can be applied to the field of technology that implements various products that require fine-sized conductive lines or conductive patterns.

The same reference numerals refer to the same device elements throughout the specification. Even though a reference numeral might not be mentioned or described with reference to a drawing, the reference numeral may be mentioned or described with reference to another drawing. In addition, even though a reference numeral might not be shown in a drawing, it may be shown in another drawing.

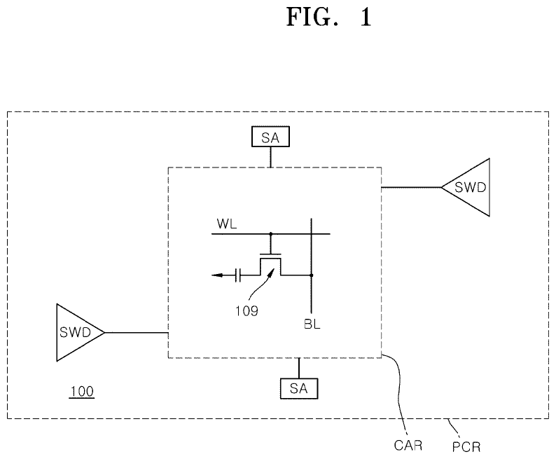

FIG. 1 is a schematic view illustrating a semiconductor device according to an embodiment of the present disclosure.

Referring to FIG. 1, the semiconductor device includes at least one cell device 109 and peripheral circuits which are integrated on a semiconductor substrate 100. The semiconductor substrate 100 includes a semiconductor material. For example, the semiconductor substrate 100 may be a silicon (Si) substrate, a germanium (Ge) substrate, or a silicon-germanium (SiGe) substrate. The substrate 100 includes a cell array region CAR and a peripheral circuit region PCR.

Although a one cell device 109 is shown in FIG. 1, the semiconductor device includes a plurality of cell devices (hereinafter referred to as the cell devices 109). The cell devices 109 are arranged in the cell array region CAR. The cell devices 109 may be memory devices. Each of the memory devices 109 may be a DRAM device. Each of the memory devices 109 includes a transistor and a data storage device. The data storage device may be a capacitor. The cell devices 109 are arranged in the cell array region CAR to be connected to word lines WL and bit lines BL.

The peripheral circuits are arranged in the peripheral circuit region PCR. The peripheral circuits may be sub-word line drivers SWD or sense amplifiers SA. The sub-word line drivers SWD are arranged on the left and right sides of the cell array region CAR to be connected to the corresponding word lines WL. The sense amplifiers SA are arranged above and below the cell array region CAR to be connected to the corresponding bit lines BL. Peripheral circuits such as row decoders, column decoders, and control circuits may be further arranged in the peripheral circuit region PCR.

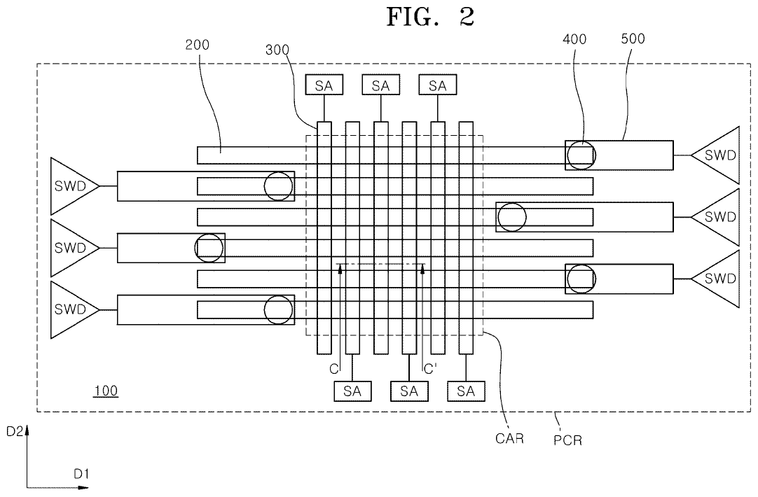

FIG. 2 is a schematic plan view illustrating a semiconductor device according to an embodiment of the present disclosure.

Referring to FIG. 2, the semiconductor device includes an array of lower conductive lines 200, an array of middle conductive lines 300, and an array of upper conductive lines 500. The arrays of the conductive lines 200, 300 and 500 are located at different heights from the semiconductor substrate 100. In some embodiments, the lower conductive lines 200 are located closer to the semiconductor substrate 100 than the middle conductive lines 300 and the upper conductive lines 500. The middle conductive lines 300 are located closer to the semiconductor substrate 100 than the upper conductive lines 500 and located farther from the semiconductor substrate 100 than the lower conductive lines 200. The upper conductive lines 500 are located farther from the semiconductor substrate 100 than the middle conductive lines 300 and the lower conductive lines 200.

The lower conductive lines 200 may be the word lines (WL in FIG. 1) connected to the cell devices (109 in FIG. 1) arranged in the cell array region CAR. The lower conductive lines 200 may be gate patterns of transistors constituting the cell devices (109 in FIG. 1). Each of the lower conductive lines 200 may include a metal pattern including at least one of tungsten (W), titanium (Ti), tantalum (Ta), and conductive nitrides thereof. Each of the lower conductive lines 200 may include a semiconductor pattern including polycrystalline silicon doped with a p-type or n-type impurity. Each of the lower conductive lines 200 may include a composite layer of a metal pattern and a semiconductor pattern.

The middle conductive lines 300 may be patterns extending in a second direction D2 perpendicular to a first direction D1 in which the lower conductive lines 200 extend. The middle conductive lines 300 20 may be bit lines (BL in FIG. 1) connected to the cell devices (109 in FIG. 1) arranged in the cell array region CAR. The bit lines BL extend in the second direction D2 that intersects the word lines WL. Each of the middle conductive lines 300 may include a semiconductor pattern including polysilicon doped with an impurity. Each of the middle conductive lines 300 may include a metal pattern including a metal material such as tungsten (W), titanium (Ti), and tantalum (Ta) or a conductive metal nitride such as titanium nitride, tantalum nitride, or tungsten nitride. Each of the middle conductive lines 300 may include a composite layer of a metal pattern and a semiconductor pattern.

The upper conductive lines 500 extend in the first direction D1 in which the lower conductive lines 200 extend. A portion of each of the upper conductive lines 500 overlaps with a portion of each of the lower conductive lines 200, and each of the upper conductive lines 500 extends outside each of the lower conductive lines 200. Each of the upper conductive lines 500 may include a metal material such as tungsten (W). Each of the upper conductive lines 500 may further include a barrier layer including titanium (Ti), tungsten nitride (TiN), or tungsten silicon nitride (WSiN).

The upper conductive lines 500 connect the lower conductive lines 200 to the corresponding sub-word line drivers SWD. The lower conductive lines 200 extend across the cell array region CAR and into the peripheral circuit region PCR. The upper conductive lines 500 are located in the peripheral circuit region PCR, and each of the upper conductive lines 500 is connected to the corresponding lower conductive line 200 through a conductive contact 400. Each of the conductive contacts 400 may include a metal material such as tungsten (W). The conductive contacts 400 are disposed in the peripheral circuit region PCR.

The groups of the sub-word line drivers SWD are arranged in the peripheral circuit region PCR on the left and right sides of the cell array region CAR, with the cell array region CAR therebetween. The lower conductive lines 200 are connected to the sub-word line drivers SWD one by one. The lower conductive lines 200 are alternately connected to the sub-word line drivers SWD on the left and right sides of the cell array region CAR. In FIG. 2, even lower conductive lines 200 are connected to even sub-word line drivers SWD located on the left side of the cell array region CAR, respectively, and odd lower conductive lines 200 are connected to odd sub-word line drivers SWD located on the right side of the cell array region CAR, respectively.

The number of upper conductive lines 500 arranged on the left or right side of the cell array region CAR may be reduced to half of the number of neighboring lower conductive lines 200. Half of the upper conductive lines 500 are arranged on the left side of the cell array region CAR, and the remaining upper conductive lines 500 are arranged on the left or right side of the cell array region CAR. In FIG. 2, even upper conductive lines 500 are arranged on the left side of the cell array region CAR, and odd upper conductive lines 500 are arranged on the left or right side of the cell array region CAR. A separation distance between neighboring upper conductive lines 500 may be secured to be wider than a separation distance between neighboring lower conductive lines 200. Accordingly, electrical isolation between the upper conductive lines 500 may be secured more reliably. Electrical isolation between the conductive contacts 400 connected to the upper conductive lines 500 may be further secured. The conductive contacts 400 may be arranged in a zig-zag fashion along the second direction D2. Accordingly, the separation distance between neighboring conductive contacts 400 may be secured to be greater than the separation distance between the upper conductive lines 500 along the second direction D2. Accordingly, the electrical isolation between the conductive contacts 400 may be further secured.

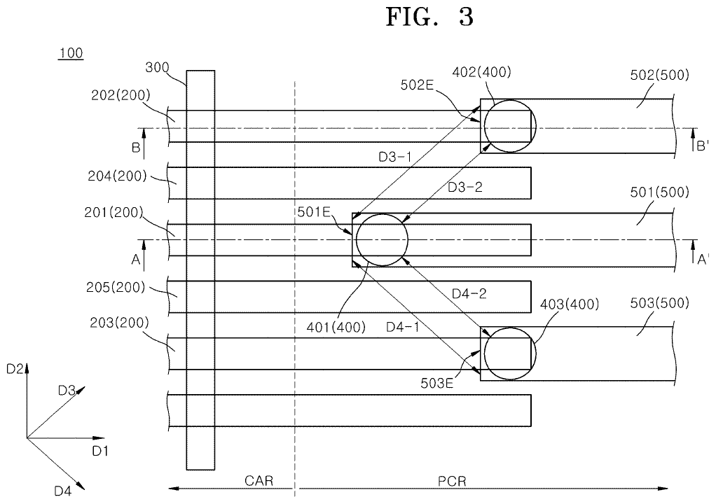

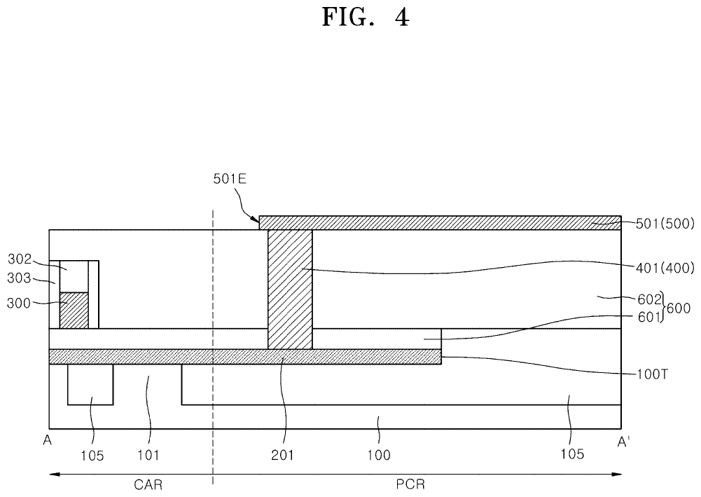

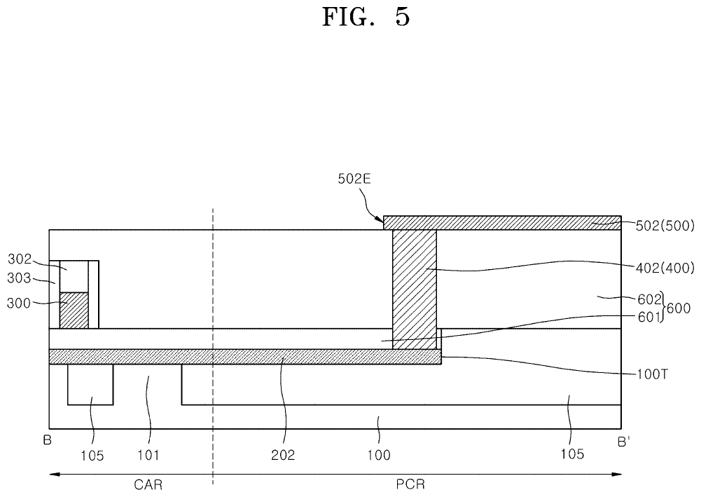

FIG. 3 is a schematic plan view illustrating the array of the upper conductive lines 500 of the semiconductor device in FIG. 2. FIG. 4 is a schematic cross-sectional view illustrating a cross-sectional shape along a line A-A′ in FIG. 3. FIG. 5 is a schematic cross-sectional view illustrating a cross-sectional shape along a line B-B′ in FIG. 3.

Referring to FIG. 3, the array of lower conductive lines 200 arranged over the semiconductor substrate 100 includes a first lower conductive line 201 and a second lower conductive line 202. The first lower conductive line 201 and the second lower conductive line 202 are spaced apart from each other in the second direction D2. The array of the lower conductive lines 200 may further include a third lower conductive line 203 spaced apart from the first lower conductive line 201 in the second direction D2. The third lower conductive line 203 is arranged in an opposite position to the second lower conductive line 202 so that the first lower conductive line 201 is arranged between the second lower conductive line 202 and the third lower conductive line 203. The array of the lower conductive lines 200 may further include a fourth lower conductive line 204 arranged between the first lower conductive line 201 and the second lower conductive line 202. The array of the lower conductive lines 200 may further include a fifth lower conductive line 205 arranged between the first lower conductive line 201 and the third lower conductive line 203. The fourth and fifth lower conductive lines 204 and 205 do not overlap and are not connected to the first, second, and third upper conductive lines 501, 502 and 503.

The array of upper conductive lines 500 arranged over the peripheral region PCR of the semiconductor substrate 100 include a first upper conductive line 501 and a second upper conductive line 502. The array of the upper conductive lines 500 may further include a third upper conductive line 502 spaced apart from the first upper conductive line 501 in the second direction D2. The third upper conductive line 503 is arranged in an opposite position to the second upper conductive line 502 so that the first upper conductive line 501 is arranged between the third upper conductive line 503 and the second upper conductive line 502.

Referring to FIGS. 3, 4, and 5, the semiconductor device may further include a first insulation layer 600 that is formed to cover the lower conductive lines 200 including the first lower conductive line 201 and the second lower conductive line 202 to electrically isolate the first lower conductive line 201 and the second lower conductive line 202. The upper conductive lines 500 including the first upper conductive line 501 and the second upper conductive line 502 may be arranged on the first insulation layer 600. Accordingly, the upper conductive lines 500 are located farther from the semiconductor substrate 100 than the lower conductive lines 200.

The semiconductor substrate 100 includes an active region 101 and isolation regions 105. Each of the isolation regions 105 includes an insulating material. Each of the isolation regions 105 may include an insulating material such as silicon oxide, silicon nitride, and/or silicon oxynitride. The active region 101 may be a portion of the semiconductor substrate 100, surrounded and partitioned by the isolation regions 105.

The semiconductor substrate 100 further includes trenches 100T. The trenches 100T are formed under a surface of the semiconductor substrate 100 contacting the first insulation layer 600. The trenches 100T may be recesses formed under the surface of the semiconductor substrate 100. The lower conductive lines 200 including the first lower conductive line 201 and the second lower conductive line 202 are located within the trenches 100T. A dielectric layer (not shown) may be formed at an interface between the semiconductor substrate 100 and the lower conductive lines 200 including the first lower conductive line 201 and the second lower conductive line 202 within the trenches 100T. The dielectric layer (not shown) may include a silicon oxide layer, a silicon nitride layer, and/or a silicon oxynitride layer. The dielectric layer (not shown) may serve as a gate dielectric layer when the lower conductive lines 200 serve as gate patterns.

The first insulation layer 600 includes a first lower insulation layer 601 and a second lower insulation layer 602. The first lower insulation layer 601 fills the trenches 100T to electrically isolate the lower conductive lines 200. The first lower insulation layer 601 may be a word line capping layer that is formed to cover the lower conductive lines 200. The first lower insulation layer 601 may include an insulating material such as silicon oxide, silicon nitride, and/or silicon oxynitride.

The array of the middle conductive lines 300, which are the bit lines BL, is disposed on the first lower insulation layer 601 and/or the semiconductor substrate 100. A bit line capping layer 302 is formed on the middle conductive lines 300, and a spacer 303 is formed on a sidewall of each of the middle conductive lines 300. The bit line capping layer 302 may include a silicon oxide layer, a silicon nitride layer, and/or a silicon oxynitride layer. The spacer 303 may include a silicon oxide layer, a silicon nitride layer, and/or a silicon oxynitride layer. The second lower insulation layer 602 may be formed as an interlayer insulation layer that is formed to cover a portion of the semiconductor substrate 100, a portion of the first lower insulation layer 601, the middle conductive lines 300, and the like. The second lower insulation layer 602 may include an insulating material such as silicon oxide, silicon nitride, or/and silicon oxynitride.

Referring to FIG. 3, the first, second, and third upper conductive lines 501, 502, and 503 extend outward from the first, second, and third lower conductive lines 201, 202, and 203, respectively, in the first direction D1. The first upper conductive line 501 includes a first end 501E located over at least a portion of the first lower conductive line 201. That is, the first end 501E of the first upper conductive line 501 overlaps a portion of the first lower conductive line 201 in the plan view. The second upper conductive line 502 includes a second end 502E located over at least a portion of the second lower conductive line 202. That is, the second end 502E of the second upper conductive line 502 overlaps a portion of the second lower conductive line 202 in the plan view. The first upper conductive line 501 and the second upper conductive line 502 are arranged so that the second end 502E of the second upper conductive line 502 is located spaced apart (D3-1) from the first end 501E of the first upper conductive line 501 in a first diagonal direction D3 with respect to the first direction D1 in which the first and second lower conductive lines 201 and 202 extend.

The third upper conductive line 503 includes a third end 503E located over at least a portion of the third lower conductive line 203. That is, the third end 503E of the third upper conductive line 503 overlaps a portion of the third lower conductive line 203 in the plan view. The first upper conductive line 501 and the third upper conductive line 503 are arranged so that the third end 503E of the third upper conductive line 503 is located spaced apart (D4-1) from the first end 501E of the first upper conductive line 501 in a second diagonal direction D4. The first diagonal direction D3 may be a diagonal direction between the first direction D1 and the second direction D2, and the second diagonal direction D4 may be a diagonal direction intersecting the first diagonal direction D3. The second end 502E of the second upper conductive line 502, the first end 501E of the first upper conductive line 501, and the third end 503E of the third upper conductive line 503 may be arranged in a zig-zag fashion along the second direction D2 in which the middle conductive lines 300 extend. The first, second, and third upper conductive lines 501, 502, and 503 are arranged so that the first end 501E of the first upper conductive line 501 is located closer to the cell array region CAR than the second end 502E of the second upper conductive line 502 and the third end 503E of the third upper conductive line 503.

Referring to FIGS. 3, 4, and 5, a first contact 401, which is one of the conductive contacts 400, connects the first upper conductive line 501 to the first lower conductive line 201. A second contact 402, which is another one of the conductive contacts 400, connects the second upper conductive line 502 to the second lower conductive line 202. The first contact 401 and the second contact 402 may substantially penetrate the first insulation layer 600 to contact the first and second lower conductive lines 201 and 202, respectively. A third contact 403, which is another one of the conductive contacts 400, connects the third upper conductive line 503 to the third lower conductive line 203. The second contact 402 is spaced apart (D3-2) from the first contact 401 in the first diagonal direction D3. The third contact 403 is spaced apart (D4-2) from the first contact 401 in the second diagonal direction D4. The second contact 402, the first contact 401, and the third contact 403 may be arranged in a zig-zag fashion along the second direction D2. The first contact 401, the second contact 402, and the third contact 403 are arranged so that the first contact 401 is located closer to the cell array region CAR than the second contact 402 and the third contact 403.

The arrangement including the first lower conductive line 201, the first contact 401, the first upper conductive line 501, the fourth lower conductive line 204, the second lower conductive line 202, the second contact 402, and the second upper conductive line 502 may be further repeated along the second direction D2.

Referring to FIGS. 2 and 3, the first lower conductive line 201 may be connected to the sub-word line driver SWD nearby the first upper conductive line 501 through a connection path formed by the first contact 401 and the first upper conductive line 501. The second lower conductive line 202 may be connected to another sub-word line driver SWD nearby the second upper conductive line 502 through a connection path formed by the second contact 402 and the second upper conductive line 502.

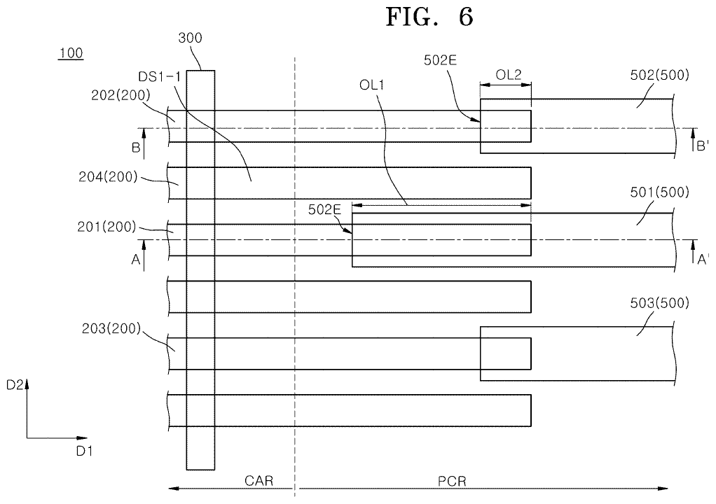

FIG. 6 is a schematic plan view illustrating the array of the upper conductive lines 500 of the semiconductor device in FIG. 2.

Referring to FIG. 6, the first lower conductive line 201 among the lower conductive lines 200 is arranged to partially overlap the first upper conductive line 501 in the plan view. That is, a portion of the first lower conductive line 201 is located over at least a portion of the first upper conductive line 501. The second lower conductive line 202, which is another one of the lower conductive lines 200, partially overlaps the second upper conductive line 502 in the plan view. That is, a portion of the second lower conductive line 202 is located over at least a portion of the second upper conductive line 502. As the second end 502E of the second upper conductive line 502 is located farther from the cell array region CAR than the first end 501E of the first upper conductive line 501, a first width OL1 of a portion where the first upper conductive line 501 and the first lower conductive line 201 overlap each other is greater than a second width OL2 of the portion where the second upper conductive line 502 and the second lower conductive line 202 overlap each other. The first width OL1 may be the width of the overlapping portion in the first direction D1 in which the first lower conductive line 201 extends. The second width OL2 may be the width of the overlapping portion in the first direction D1 where the second lower conductive line 202 extends.

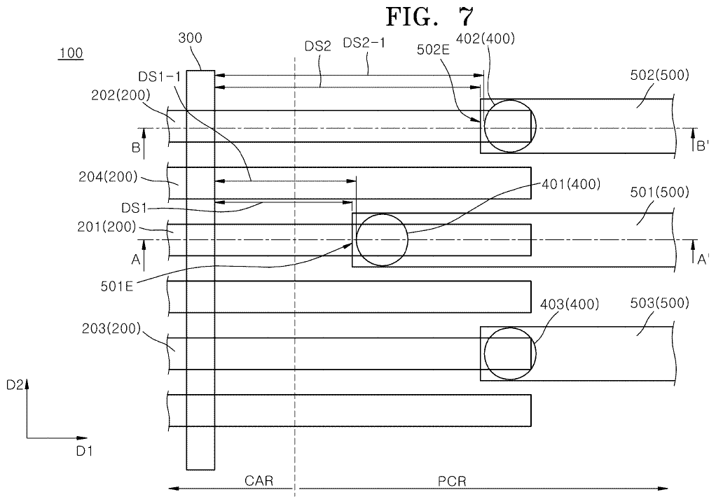

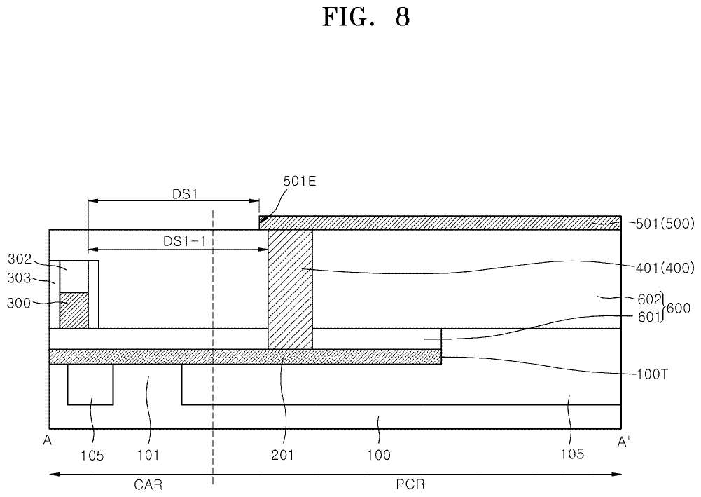

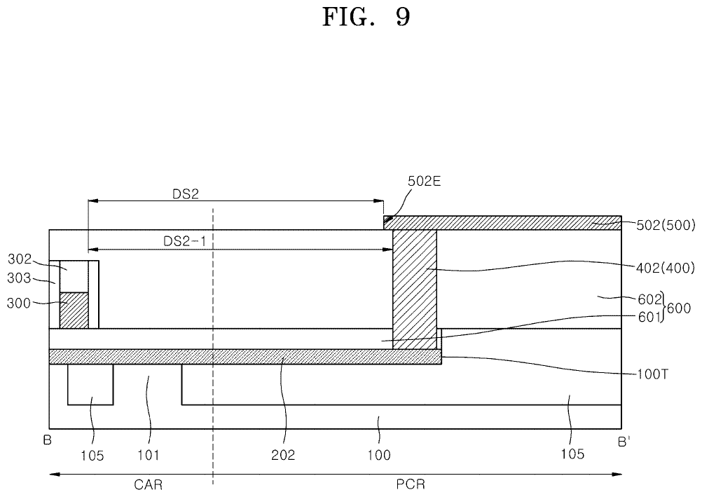

FIG. 7 is a schematic plan view illustrating the array of the upper conductive lines 500 of the semiconductor device in FIG. 2. FIG. 8 is a schematic cross-sectional view illustrating a cross-sectional shape along a line A-A′ in FIG. 7. FIG. 9 is a schematic cross-sectional view illustrating a cross-sectional shape along a line B-B′ in FIG. 7.

Referring to FIGS. 7, 8, and 9, the semiconductor device includes an array of the first lower conductive line 201 and second lower conductive line 202, the middle conductive line 300, the first upper conductive line 501 and second upper conductive line 502 that are arranged over the first insulation layer 600, and the first and second contacts 401 and 402. The first upper conductive line 501 and the second upper conductive line 502 may be arranged so that a first distance DS1 in which the first end 501E of the first upper conductive line 501 is spaced apart from the middle conductive line 300 is shorter than a second distance DS2 in which the second end 502E of the second upper conductive line 502 is spaced apart from the middle conductive line 300. The arrangement including the first upper conductive line 501 and the second upper conductive line 502 may be further repeated along the second direction D2. The first contact 401 and the second contact 402 may be arranged so that a third distance DS1-1 in which the first contact 401 is spaced apart from the middle conductive line 300 is shorter than a fourth distance DS2-1 in which the second contact 402 is spaced apart from the middle conductive line 300. The arrangement including the first contact 401 and the second contact 402 may be further repeated along the second direction D2.

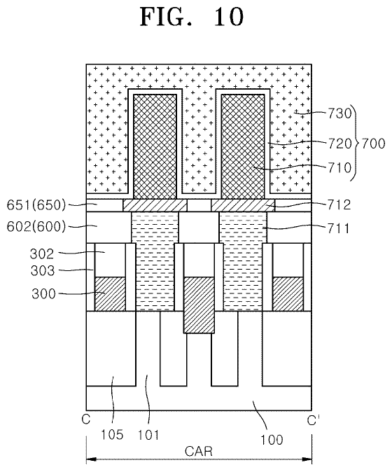

FIG. 10 is a schematic cross-sectional view illustrating the semiconductor device in FIG. 2. FIG. 10 is a schematic cross-sectional view illustrating a cross-sectional shape along a line C-C′ in FIG. 2.

Referring to FIGS. 2 and 10, the semiconductor device may further include capacitors 700 disposed over the semiconductor substrate 100. The capacitors 700 may be located farther from the semiconductor substrate 100 than the upper conductive lines 500. Each of the capacitors 700 may be formed as a data storage device constituting the cell device (109 in FIG. 1) with a transistor. Each of the capacitors 700 includes a storage node 710, a capacitor dielectric layer 720, and a plate node 730.

The storage node 710 of each of the capacitors 700 may have a conductive pillar feature. The storage node 710 of the capacitor 700 may be formed in a conductive cylindric feature. The storage node 710 of the capacitor 700 may include a layer containing metal such as titanium nitride (TiN). The storage node 710 of the capacitor 700 may further include a doped polysilicon layer formed on the titanium nitride (TiN) layer.

The capacitor dielectric layer 720 may include a high-dielectric material layer having a high dielectric constant k. The capacitor dielectric layer 720 may include zirconium oxide (ZrO₂), aluminum oxide (Al₂O₃), or tantalum oxide (Ta₂O₅).

The plate node 730 may include various electrode materials. The plate node 730 may include a titanium nitride (TiN) layer. The plate node 730 may further include a conductive silicon layer such as a silicon germanium (SiGe) layer covering the titanium nitride (TiN) layer. The plate node 730 may be a blanket-featured conductive layer that extends to overlap a plurality of storage nodes 710.

The storage nodes 710 of the capacitors 700 are connected to the active region 101 of the semiconductor substrate 100 by storage node contacts 711. Each of the storage node contacts 711 may include a conductive material such as impurity-doped polysilicon. Each of the storage node contacts 711 may have a feature of a plug that penetrates the first insulation layer 600 or the second lower insulation layer 602. Conductive pads 712 may be disposed between the storage node contacts 711 and the storage nodes 710. The conductive pads 712 may be formed of substantially the same conductive material as the upper conductive lines 500. A first upper insulation layer 651 that insulates the conductive pads 712 from each other may be formed on the first insulation layer 600 as a portion of a second insulation layer 650.

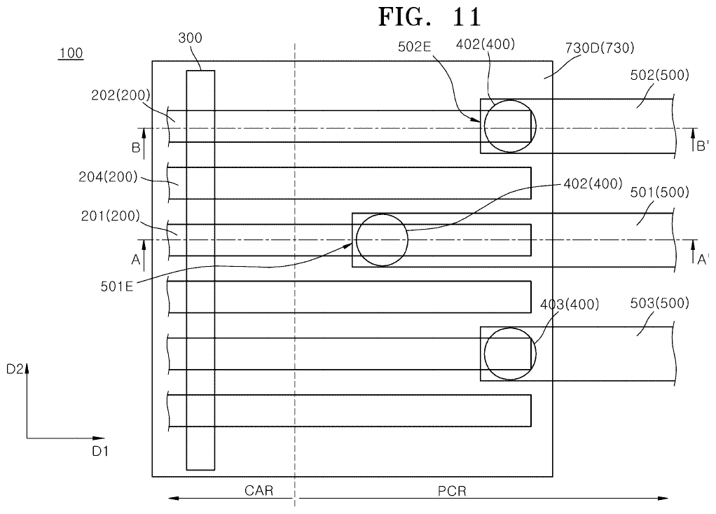

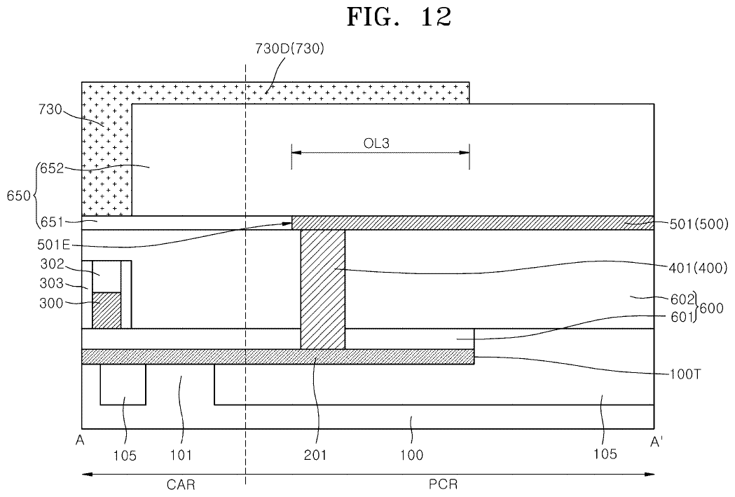

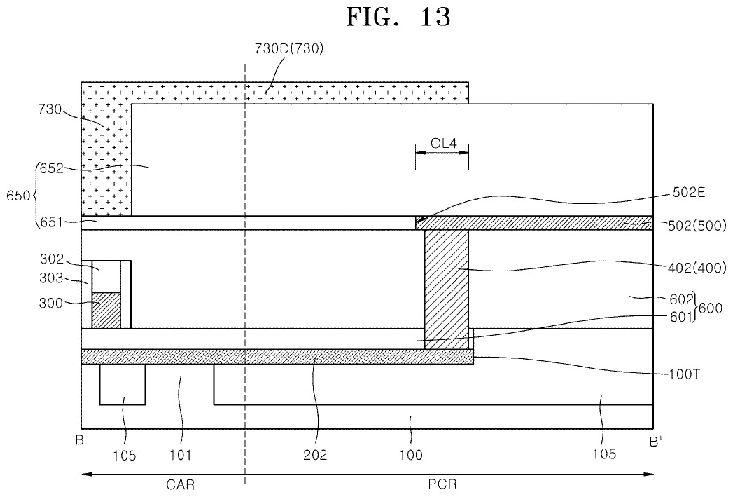

FIG. 11 is a schematic plan view illustrating the upper conductive lines 500 and the plate node 730 of the semiconductor device according to an embodiment of the present disclosure. FIG. 12 is a schematic cross-sectional view illustrating a cross-sectional shape along a line A-A′ in FIG. 11. FIG. 13 is a schematic cross-sectional view illustrating a cross-sectional shape along a line B-B′ in FIG. 11.

Referring to FIGS. 2, 10, and 11, the storage node contacts 711 and the storage nodes 710 of the capacitors 700 are located in the cell array region CAR of the semiconductor substrate 100. The storage node contacts 711 and the storage nodes 710 of the capacitors 700 are not located in the peripheral region PCR of the semiconductor substrate 100. The plate node 730 of each of the capacitors 700 may have a blanket feature, and a portion of the plate node 730 may extend onto the peripheral circuit region PCR.

Referring to FIGS. 11, 12, and 13, an extended portion 730D of the plate node 730 may be a portion located on the second insulation layer 650. The second insulation layer 650 may be an interlayer insulation layer that is formed to cover the upper conductive lines 500 to electrically isolate the upper conductive lines 500. The second insulation layer 650 includes a first upper insulation layer 651 and a second upper insulation layer 652. The second insulation layer 650 may include silicon oxide, silicon nitride, or silicon oxynitride. The extended portion 730D of the plate node 730 may extend onto the peripheral circuit region PCR of the semiconductor substrate 100 to be located over at least a portion of the first upper conductive line 501 and a portion of the second upper conductive line 502.

Because the second end 502E of the second upper conductive line 502 is located farther from the cell array region CAR than the first end 501E of the first upper conductive line 501, a third width OL3 of the portion in which extended portion 730D of the plate node 730 is located over the first upper conductive line 501 is greater than a fourth width OL4 of a portion in which the extended portion 730D of the plate node 730 is located over the second upper conductive line 502.

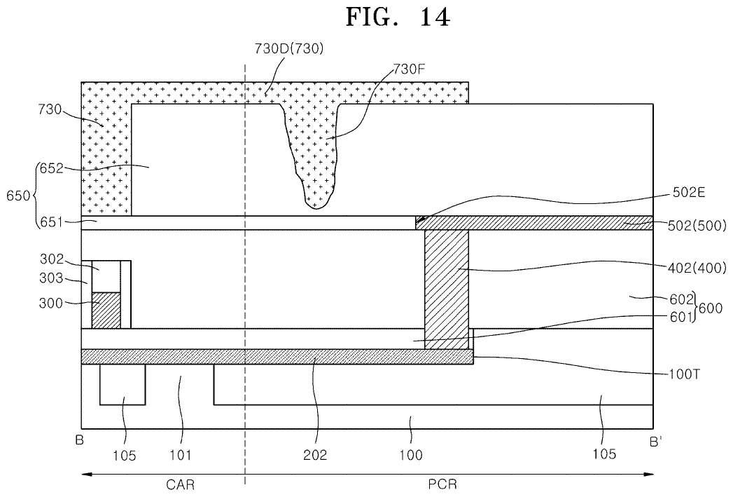

FIG. 14 is a schematic plan view illustrating the effect of the array of the upper conductive lines 500 of the semiconductor device according to an embodiment of the present disclosure.

Referring to FIGS. 12, 13, and 14, the fourth width OL4 of the portion in which the extended portion 730D of the plate node 730 is located over the second upper conductive line 502 can be reduced to be smaller than the third width OL3. Accordingly, electrical short-circuiting of the second upper conductive line 502 with the extended portion 730D of the plate node 730 can be reduced or suppressed. Therefore, electrical isolation between the second upper conductive line 502 and the extended portion 730D of the plate node 730 can be improved.

Referring to FIG. 14 along with FIG. 10, by the process of forming the capacitors 700, a defect in which a portion of the second insulation layer 650 is lost may occur undesirably. When such loss occurs in a portion of the second insulation layer 650, located in the peripheral circuit region PCR, the conductive material constituting the plate node 730 may penetrate into the lost portion of the second insulation layer 650, resulting in a defect 730F. When such defect 730F is connected to the upper conductive lines 500, a defect may occur in which the upper conductive lines 500 and the plate node 730 are electrically shorted. As shown in FIG. 7, because the second end 502E of the second upper conductive line 502 is located farther from the cell array region CAR than the first end 501E of the first upper conductive line 501, the second end 502E of the second upper conductive line 502 may be located farther away from the defect 730F in which the conductive material is penetrated into the second insulation layer 650 than the first end 501E. Accordingly, an electrical defect formed when the second upper conductive line 502 is connected to a defect 730F in which the conductive material penetrates into the second insulating layer 650 can be reduced or suppressed.

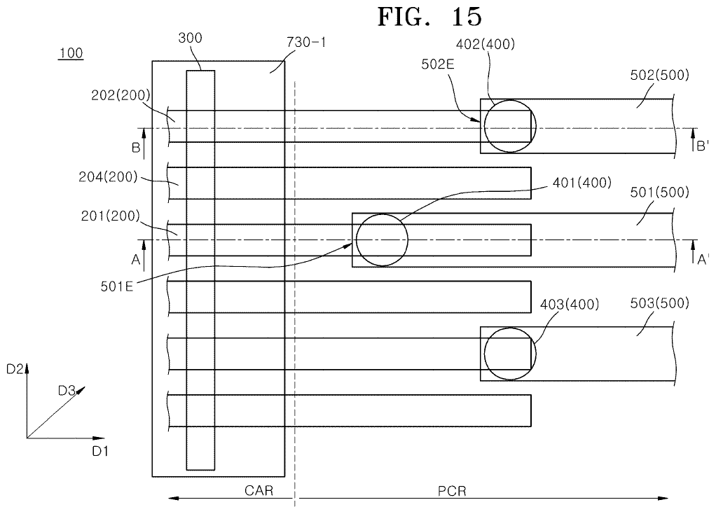

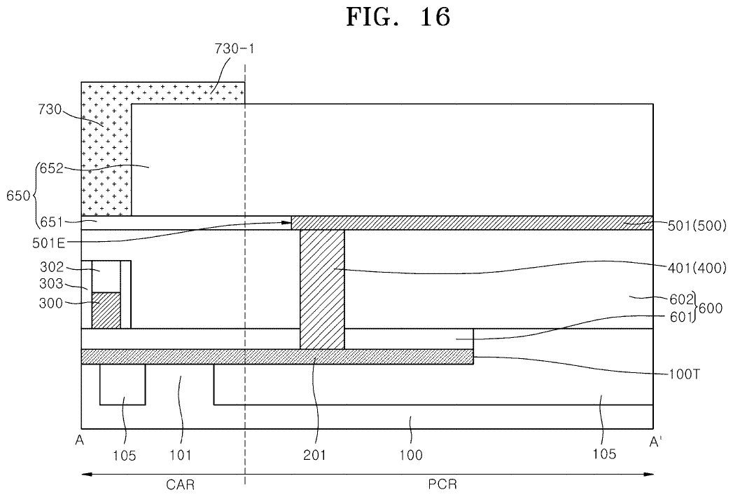

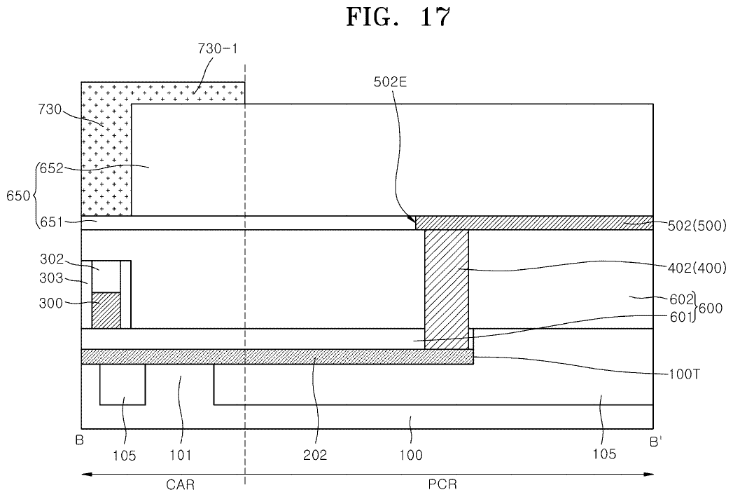

FIG. 15 is a schematic plan view illustrating the upper conductive lines 500 and a plate node 730-1 of the semiconductor device according to an embodiment of the present disclosure. FIG. 16 is a schematic cross-sectional view illustrating a cross-sectional shape along a line A-A′ in FIG. 15. FIG. 17 is a schematic cross-sectional view illustrating a cross-sectional shape along a line B-B′ in FIG. 15.

Referring to FIGS. 15, 16, and 17 along with FIG. 10, the semiconductor device includes the array of the lower conductive lines 200 including the first lower conductive line 201 and the second lower conductive line 202, the array of the upper conductive lines 500 including the first upper conductive line 501 and the second upper conductive line 502, and the array of the conductive contacts 400 including the first contact 401 and the second contact 402, which are disposed over the semiconductor substrate 100. The semiconductor device further includes the storage nodes 710, the capacitor dielectric layer 720, and the plate nodes 730. The plate node 730-1 is spaced apart from the first end 501E of the first upper conductive line 501 and the second end 502E of the second upper conductive line 502 in the first direction D1.

Because the first end 501E of the first upper conductive line 501 and the second end 502E of the second upper conductive line 502 are spaced apart from the plate node 730-1 in the first direction D1, the plate node 730-1 is not located over the first upper conductive line 501 and the second upper conductive line 502. Accordingly, even when the defect 730F occurs in which the conductive material constituting the plate node 730-1 penetrates into the second insulation layer 650 as shown in FIG. 14, the electrical defect in which the defect 730F is connected to the first upper conductive line 501 and the second upper conductive line 502 and an electrical short-circuiting occurs can be reduced or suppressed. The second end 502E of the second upper conductive line 502 may be located farther from the cell array region CAR than the first end 501E of the first upper conductive line 501. Accordingly, the conductive material may be spaced further away from the defect 730F that penetrates into the second insulation layer 650. Therefore, the electrical defects in which the conductive material of the second upper conductive line 502 is connected to the defect 730F penetrating the second insulation layer 650 can be further reduced or suppressed.

The inventive concept has been disclosed in conjunction with some embodiments as described above. Those skilled in the art will appreciate that various modifications, additions and substitutions are possible, without departing from the scope and spirit of the present disclosure. Accordingly, the embodiments disclosed in the present specification should be considered from not a restrictive standpoint but an illustrative standpoint. The scope of the inventive concept is not limited to the above descriptions but defined by the accompanying claims, and all distinctive features in the equivalent scope should be construed as being included in the inventive concept. Furthermore, the embodiments may be combined to form additional embodiments.

What is claimed is:

1. A semiconductor device comprising:
a first lower conductive line and a second lower conductive line that are arranged over a semiconductor substrate;
an insulation layer that covers the first and second lower conductive lines;
a first upper conductive line and a second upper conductive line that are arranged over the insulation layer;
a first contact that connects the first upper conductive line to the first lower conductive line; and
a second contact that connects the second upper conductive line to the second lower conductive line,
wherein the first upper conductive line includes a first end located over at least a portion of the first lower conductive line,
wherein the second upper conductive line includes a second end located over at least a portion of the second lower conductive line, and
wherein the second end is spaced apart from the first end in a first diagonal direction with respect to a first direction in which the first and second lower conductive lines extend.

2. The semiconductor device of claim 1, wherein the first contact penetrates the insulation layer to contact the first lower conductive line.

3. The semiconductor device of claim 1, wherein the second contact is spaced apart from the first contact in the first diagonal direction.

4. The semiconductor device of claim 1, wherein the first and second upper conductive lines extend outside the first and second lower conductive lines in the first direction.

5. The semiconductor device of claim 1,
wherein the semiconductor substrate further includes first and second trenches, and
wherein the first and second lower conductive lines are located in the first and second trenches, respectively.

6. The semiconductor device of claim 1, wherein the first and second lower conductive lines are word lines.

7. The semiconductor device of claim 6, further comprising bit lines extending in a second direction intersecting the word lines.

8. The semiconductor device of claim 1, further comprising sub-word line drivers connected to the first and second upper conductive lines.

9. The semiconductor device of claim 1, further comprising:
a third lower conductive line arranged at an opposite position to the second lower conductive line, the first lower conductive line being arranged between the second lower conductive line and the third lower conductive line;
a third upper conductive line arranged at an opposite position to the second upper conductive line, the first upper conductive line being arranged between the second upper conductive line and the third upper conductive line; and
a third contact connecting the third upper conductive line to the third lower conductive line,
wherein the third upper conductive line includes a third end located over at least a portion of the third lower conductive line, and
wherein the third end is spaced apart from the first end in a second diagonal direction intersecting the first diagonal direction.

10. The semiconductor device of claim 9, wherein the third contact is spaced apart from the first contact in the second diagonal direction.

11. The semiconductor device of claim 1, further comprising a fourth lower conductive line that is arranged between the second lower conductive line and the first lower conductive line and is not located over the first and second upper conductive lines.

12. The semiconductor device of claim 1, wherein a first width of a portion of the first upper conductive line, located over the first lower conductive line is greater than a second width of a portion of the second upper conductive line, located over the second lower conductive line.

13. The semiconductor device of claim 1, further comprising:
a storage node connected to the semiconductor substrate;
a capacitor dielectric layer covering the storage node; and
a plate node covering the capacitor dielectric layer.

14. The semiconductor device of claim 13,
wherein the plate node includes an extended portion located over at least a portion of each of the first and second upper conductive lines, and
wherein a third width of a portion of the extended portion of the plate node, located over at least a portion of the first upper conductive line is greater than a fourth width of a portion of the extended portion of the plate node, located over at least of the second upper conductive line.

15. The semiconductor device of claim 13, wherein the plate node is spaced apart from the first end of the first upper conductive line and the second end of the second upper conductive line in the first direction.

16. A semiconductor device comprising:
a first lower conductive line and a second lower conductive line that are arranged over a semiconductor substrate;
a middle conductive line intersecting the first and second lower conductive lines;
an insulation layer covering the first and second lower conductive lines;
a first upper conductive line and a second upper conductive line that are arranged over the insulation layer;
a first contact that connects the first upper conductive line to the first lower conductive line; and
a second contact that connects the second upper conductive line to the second lower conductive line,
wherein a first distance in which a first end of the first upper conductive line is spaced apart from the middle conductive line is shorter than a second distance in which a second end of the second upper conductive line is spaced apart from the middle conductive line.

17. The semiconductor device of claim 16, wherein a third distance in which the first contact is spaced apart from the middle conductive line in a direction in which the first lower conductive line extends is shorter than a fourth distance in which the second contact is spaced apart from the middle conductive line.

18. The semiconductor device of claim 16, wherein the first contact penetrates the insulation layer to contact and be coupled to the first lower conductive line.

19. The semiconductor device of claim 16, wherein the first and second upper conductive lines extend outside the first and second lower conductive lines in a first direction.

20. A semiconductor device comprising:
a first lower conductive line and a second lower conductive line that are arranged over a semiconductor substrate;
a middle conductive line intersecting the first and second lower conductive lines;
an insulation layer covering the first and second lower conductive lines;
a first upper conductive line and a second upper conductive line that are arranged over the insulation layer;
a first contact connecting the first upper conductive line to the first lower conductive line;
a second contact connecting the second upper conductive line to the second lower conductive line;
a storage node connected to the semiconductor substrate;
a capacitor dielectric layer covering the storage node; and
a plate node covering the capacitor dielectric layer,
wherein the plate node is spaced apart from a first end of the first upper conductive line and a second end of the second upper conductive line in a direction in which the first lower conductive line extends.
